(19) United States
(12) Patent Application Publication
(10) Pub. No.: US 2026/0331051 A1
(43) Pub. Date: Oct. 22, 2026

(54) DISPLAY DEVICE AND ELECTRONIC DEVICE INCLUDING THE SAME

(71) Applicant: Samsung Display Co., Ltd., Yongin-si (KR)

(72) Inventors: KYUNG-BAE KIM, Yongin-si (KR); JINSEON KWAK, Yongin-si (KR); KEONMIN OH, Yongin-si (KR); Yunjang Pyun, Yongin-si (KR)

(21) Appl. No.: 19/530,720

(22) Filed: Feb. 5, 2026

(30) Foreign Application Priority Data
Feb. 18, 2025 (KR) 10-2025-0020559

(51) Int. Cl. G09G 3/3233

(52) U.S. Cl. CPC G09G 3/3233; G09G 2300/0819; G09G 2330/021

(57) ABSTRACT

A display device includes: a substrate; a light-emitting element, which is disposed on the substrate and generates light based on a driving current; and a pixel driving circuit, which is disposed on the substrate and drives the light-emitting element. The pixel driving circuit includes: a driving transistor, which generates the driving current; at least one switching transistor electrically connected to the driving transistor; and an anode initialization transistor, which receives a first initialization voltage, initializes a voltage of an anode of the light-emitting element, and is an n-type transistor. A first length of a channel of the driving transistor is greater than a second length of a channel of the anode initialization transistor. The second length of the channel of the anode initialization transistor is greater than a third length of a channel of each of the at least one switching transistor.

This application claims priority to Korean Patent Application No. 10-2025-0020559, filed on Feb. 18, 2025, and all the benefits accruing therefrom under 35 U.S.C. §119, the content of which in its entirety is herein incorporated by reference.

### BACKGROUND

### 1. Field

The present disclosure relates generally to a display device. More particularly, the present disclosure relates to a display device and an electronic device including the display device.

### 2. Description of the Related Art

With the development of information technology, the importance of a display device, which is a connection medium between a user and information, has been highlighted. For example, the use of display devices such as liquid crystal display (LCD) device, organic light emitting diode (OLED) display device, plasma display panel (PDP) device, quantum dot display device or the like is increasing.

Recently, a display device to which a high-resolution micro OLED is applied has been manufactured. A high-resolution micro OLED may be an organic light emitting diode on silicon (OLEDoS) formed using a semiconductor process on a silicon wafer substrate.

### SUMMARY

Embodiments provide a display device with reduced power consumption.

Embodiments provide an electronic device including the display device.

A display device according to an embodiment of the present disclosure includes: a substrate; a light-emitting element which is disposed on the substrate and generates light based on a driving current; and a pixel driving circuit which is disposed on the substrate and drives the light-emitting element. The pixel driving circuit includes: a driving transistor which generates the driving current; at least one switching transistor electrically connected to the driving transistor; and an anode initialization transistor which receives a first initialization voltage, initializes a voltage of an anode of the light-emitting element, and is an n-type transistor. A first length of a channel of the driving transistor is greater than a second length of a channel of the anode initialization transistor. The second length of the channel of the anode initialization transistor is greater than a third length of a channel of each of the at least one switching transistor.

In an embodiment, the substrate may include a first area in which the driving transistor and the at least one switching transistor are disposed and a second area in which the anode initialization transistor is disposed.

In an embodiment, the pixel driving circuit may further include a first body pattern to which a first power voltage having a relatively high level of voltage is applied. The first body pattern may extend in a first direction and may define a boundary between the first area and the second area.

In an embodiment, the pixel driving circuit may further include a second body pattern to which a low gate voltage having a relatively low level of voltage is applied. The second body pattern may be disposed in the second area on the substrate, have a width in the first direction, and extend in a second direction intersecting the first direction.

In an embodiment, the anode initialization transistor may include a well area comprising a source area and a drain area. The second body pattern may extend in a direction parallel to a width direction of the well area of the anode initialization transistor.

In an embodiment, each of the driving transistor, the anode initialization transistor, and the at least one switching transistor may include a body electrode. A voltage having a relatively high voltage level may be applied to the body electrode of the driving transistor and the body electrode of the at least one switching transistor. A voltage having a relatively low voltage level may be applied to the body electrode of the anode initialization transistor.

In an embodiment, a first power voltage may be applied to the body electrode of the driving transistor and the body electrode and the at least one switching transistor. A low gate voltage may be applied to the body electrode of the anode initialization transistor.

In an embodiment, the driving transistor may include a first electrode which receives a first power voltage, a gate electrode connected to a first node, and a second electrode connected to a second node. The at least one switching transistor may include: a first switching transistor including a first electrode which receives a data voltage, a gate electrode which receives a first gate signal, and a second electrode connected to a third node; and an emission control transistor including a first electrode connected to the second node, a gate electrode which receives an emission control signal, and a second electrode connected to a fourth node. The emission control transistor may electrically connect the driving transistor and the light-emitting element in response to the emission control signal.

In an embodiment, the display device may include a plurality of sub-pixels which are repeatedly disposed on the substrate along a first direction and a second direction intersecting the first direction. Each of the plurality of sub-pixels may include the light-emitting element and the pixel driving circuit.

In an embodiment, the emission control transistor may include a well area comprising a source area and a drain area. The well area of the emission control transistor of the pixel driving circuit included in a sub-pixel disposed in an N-th (wherein N is a natural number) row may be integrally formed with the well area of the emission control transistor of the pixel driving circuit included in a sub-pixel disposed in a (N+1)-th row adjacent to the N-th row in the second direction.

In an embodiment, the anode initialization transistor may provide the first initialization voltage to the fourth node in response to a third gate signal. The at least one switching transistor further may include: a second switching transistor including a first electrode connected to the first node, a gate electrode which receives a second gate signal, and a second electrode connected to the second node, the second switching transistor diode-connecting the driving transistor in response to the second gate signal; a third switching transistor including a first electrode which receives a second initialization voltage different from the first initialization voltage, a gate electrode which receives a fourth gate signal, and a second electrode connected to the third node; and a fourth switching transistor including a first electrode which receives the second initialization voltage, a gate electrode which receives a fifth gate signal, and a second electrode connected to the gate electrode of the driving transistor through the first node.

In an embodiment, each of the first switching transistor and the third switching transistor may include a well area comprising a source area and a drain area. The well area of the first switching transistor and the well area of the third switching transistor may be integrally formed.

In an embodiment, each of the second switching transistor and the fourth switching transistor may include a well area comprising a source area and a drain area. The well area of the second switching transistor and the well area of the fourth switching transistor may be integrally formed.

In an embodiment, each of the first switching transistor, the second switching transistor, the emission control transistor, the third switching transistor, and the fourth switching transistor may be a p-type transistor.

In an embodiment, the pixel driving circuit may further include a first capacitor including a first electrode connected to the gate electrode of the driving transistor through the first node and a second electrode connected to the first switching transistor through the third node.

In an embodiment, the substrate may include a silicon wafer substrate.

An electronic device according to an embodiment of the present disclosure includes: a display device including a substrate, a light-emitting element which is disposed on the substrate and generates light based on a driving current, and a pixel driving circuit which is disposed on the substrate and drives the light-emitting element; and a processor which transmits an image data signal and an input control signal to the display device. The pixel driving circuit includes: a driving transistor which generates the driving current; at least one switching transistor electrically connected to the driving transistor; and an anode initialization transistor which receives a first initialization voltage, initializes a voltage of an anode of the light-emitting element, and is an n-type transistor. A first length of a channel of the driving transistor is greater than a second length of a channel of the anode initialization transistor. The second length of the channel of the anode initialization transistor is greater than a third length of a channel of each of the at least one switching transistor.

In an embodiment, the substrate may include a first area in which the driving transistor and the at least one switching transistor are disposed and a second area in which the anode initialization transistor is disposed.

In an embodiment, the pixel driving circuit may further include a first body pattern to which a first power voltage having a relatively high level of voltage is applied and a second body pattern to which a low gate voltage having a relatively low level of voltage is applied. The first body pattern may extend in a first direction and define a boundary between the first area and the second area. The second body pattern may be disposed in the second area on the substrate, have a width in the first direction, and extend in a second direction intersecting the first direction.

In an embodiment, each of the driving transistor and the at least one switching transistor may be a p-type transistor. Each of the driving transistor, the anode initialization transistor, and the at least one switching transistor may include a body electrode. The first power voltage having the relatively high voltage level may be applied to the body electrode of the driving transistor and the body electrode of the at least one switching transistor. The low gate voltage having the relatively low voltage level may be applied to the body electrode of the anode initialization transistor.

A display device according to an embodiment of the present disclosure may include a light-emitting element that generates light based on a driving current and a pixel driving circuit that drives the light-emitting element, and the pixel driving circuit may include a driving transistor that generates the driving current, at least one switching transistor electrically connected to the driving transistor, and an anode initialization transistor that initializes a voltage of an anode of the light-emitting element and is an n-type transistor. A first length of a channel of the driving transistor may be greater than a second length of a channel of the anode initialization transistor, and the second length of the channel of the anode initialization transistor may be greater than a third length of a channel of the at least one switching transistor.

By designing the second length of the channel of the anode initialization transistor to be relatively greater than the third length of the channel of the at least one switching transistor, a leakage current generated in the anode initialization transistor while the anode initialization transistor is turned off may be relatively reduced. Accordingly, the power consumption of the display device may be relatively reduced.

### BRIEF DESCRIPTION OF THE DRAWINGS

Illustrative, non-limiting embodiments will be more clearly understood from the following detailed description in conjunction with the accompanying drawings.

FIG. 1 is a block diagram of a display device according to an embodiment of the present disclosure.

FIG. 2 is a plan view illustrating the display device of FIG. 1.

FIG. 3 is a circuit diagram illustrating an example of a circuit structure of a pixel included in the display device of FIG. 1.

FIG. 4 is a cross-sectional view illustrating a display panel included in the display device of FIG. 2.

FIG. 5 is a layout view illustrating an example of a pixel included in the display device of FIG. 1.

FIG. 6 is a block diagram of an electronic device according to an embodiment of the present disclosure.

FIG. 7 is a schematic view of an electronic device according to various embodiments.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present. It will be understood that when an element is referred to as being “connected to” another element, it can be directly connected to the other element or intervening elements may be present therebetween. In contrast, when an element is referred to as being “directly connected to” another element, there are no intervening elements present.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third,” “(4-1)-th,” “(4-2)-th,” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Hereinafter, embodiments of the present disclosure will be described in detail with reference to the accompanying drawings. The same reference numerals are used for the same components in the drawings, and redundant descriptions of the same components will be omitted.

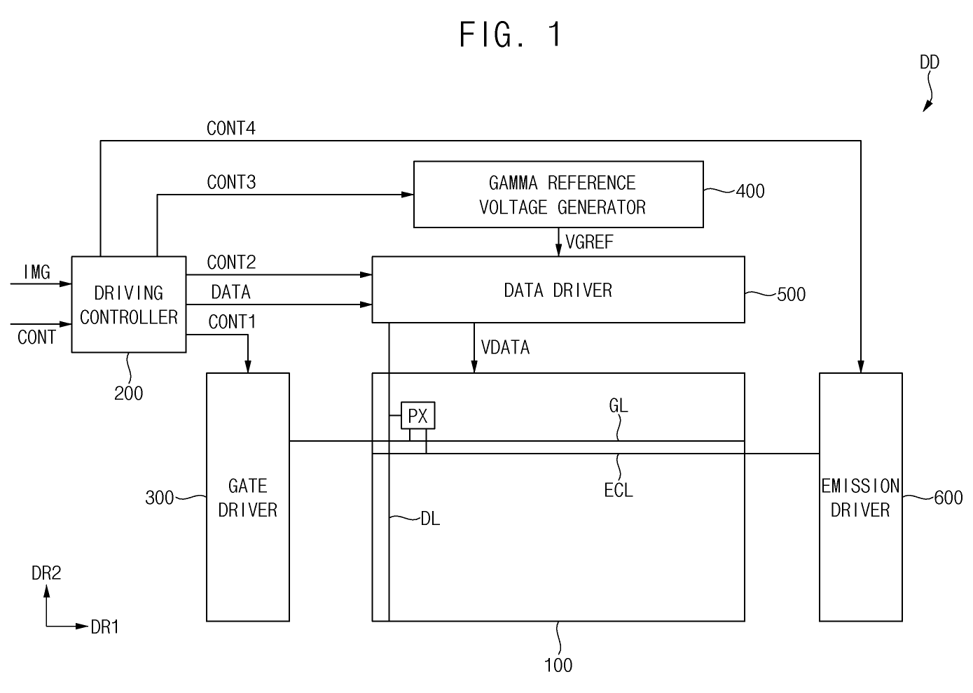

FIG. 1 is a block diagram of a display device according to an embodiment of the present disclosure.

Referring to FIG. 1, a display device DD according to an embodiment of the present disclosure may include a display panel 100 and a panel driver that drives the display panel 100. The panel driver may include a controller 200, a gate driver 300, a gamma reference voltage generator 400, a data driver 500, and an emission driver 600.

For example, the controller 200 and the data driver 500 may be integrally formed. A driving module in which the controller 200 and the data driver 500 are integrally formed may be referred to as a timing controller embedded data driver (TED).

The display panel 100 may include gate lines GL, emission lines ECL, data lines DL, and pixels PX. The pixels PX may be electrically connected to the gate lines GL, the emission lines ECL, and the data lines DL. Each of the pixels PX may generate light in response to a driving signal. For example, each of the gate lines GL may extend in a first direction DR1, and each of the emission lines ECL may extend in the first direction DR1. Each of the data lines DL may extend in a second direction DR2 intersecting the first direction DR1. For example, the first direction DR1 and the second direction DR2 may be perpendicular to each other.

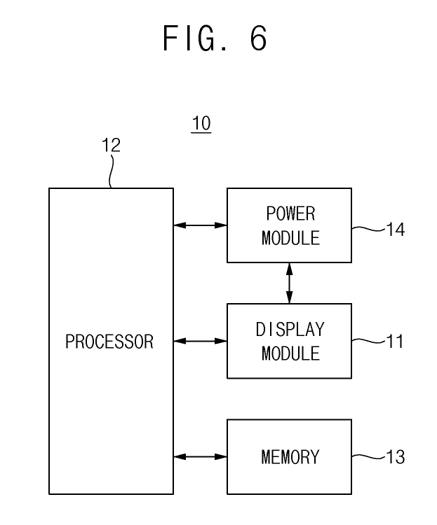

The controller 200 may receive an image data signal IMG and an input control signal CONT from an external device (e.g., a processor 12 of FIG. 6). For example, the image data signal IMG may include red image data, green image data, and blue image data. In an embodiment, the image data signal IMG may further include white image data. The input control signal CONT may include a vertical synchronization signal, a horizontal synchronization signal, a data enable signal, a master clock signal, or the like.

The controller 200 may generate a first control signal CONT1, a second control signal CONT2, a third control signal CONT3, a fourth control signal CONT4, and a data signal DATA based on the image data signal IMG and the input control signal CONT.

The controller 200 may output the first control signal CONT1 to the gate driver 300. The first control signal CONT1 may include a vertical start signal and a gate clock signal. The controller 200 may output the second control signal CONT2 and the data signal DATA to the data driver 500. The second control signal CONT2 may include a horizontal start signal and a load signal. The controller 200 may output the third control signal CONT3 to the gamma reference voltage generator 400. The controller 200 may output the fourth control signal CONT4 to the emission driver 600.

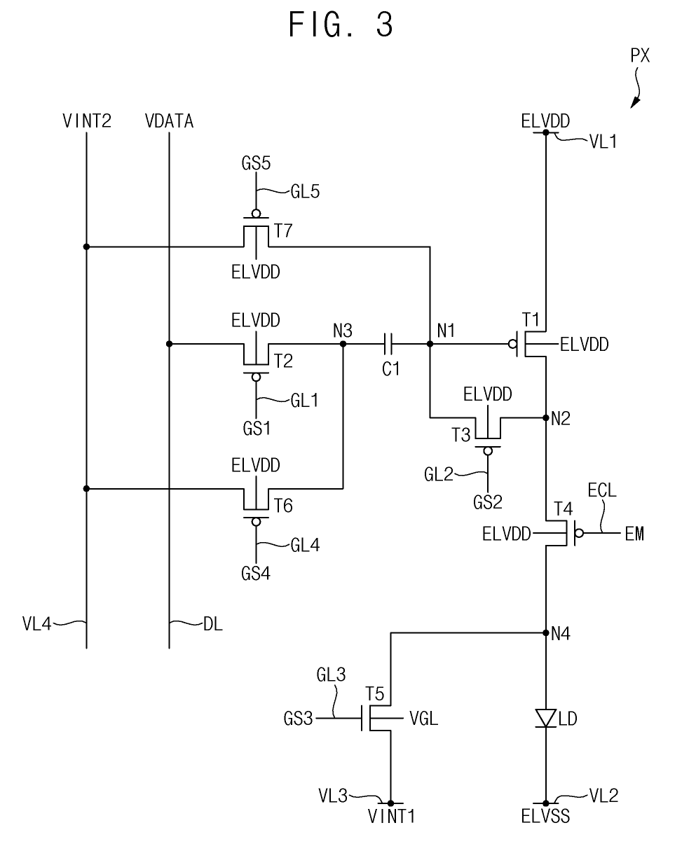

The gate driver 300 may generate gate signals in response to the first control signal CONT1. The gate driver 300 may output the gate signals to the gate lines GL. In an embodiment, the gate signals may include first to fifth gate signals GS1, GS2, GS3, GS4, and GS5 illustrated in FIG. 3. However, the present disclosure is not necessarily limited thereto.

The gamma reference voltage generator 400 may generate a gamma reference voltage VGREF in response to the third control signal CONT3. The gamma reference voltage generator 400 may provide the gamma reference voltage VGREF to the data driver 500. For example, the gamma reference voltage generator 400 may be disposed in the controller 200, or may be disposed in the data driver 500.

The data driver 500 may receive the second control signal CONT2 and the data signal DATA from the controller 200, and may receive the gamma reference voltage VGREF from the gamma reference voltage generator 400. The data driver 500 may convert the data signal DATA into an analog form of a data voltage VDATA using the gamma reference voltage VGREF. The data driver 500 may output the data voltage VDATA to the data lines DL.

The emission driver 600 may generate emission signals in response to the fourth control signal CONT4. The emission driver bmay output the emission signals to the emission lines ECL. In an embodiment, the emission signals may include an emission control signal EM illustrated in FIG. 3.

In FIG. 1, for convenience of description, the gate driver 300 is illustrated as being disposed at a first side of the display panel 100 and the emission driver 600 is illustrated as being disposed at a second side opposite the first side of the display panel 100, but the present disclosure is not necessarily limited thereto. For another example, both the gate driver 300 and the emission driver 600 may be disposed at the first side of the display panel 100. For example, both the gate driver 300 and the emission driver 600 may be disposed at opposite sides of the display panel 100. For example, the gate driver 300 and the emission driver 600 may be integrally formed.

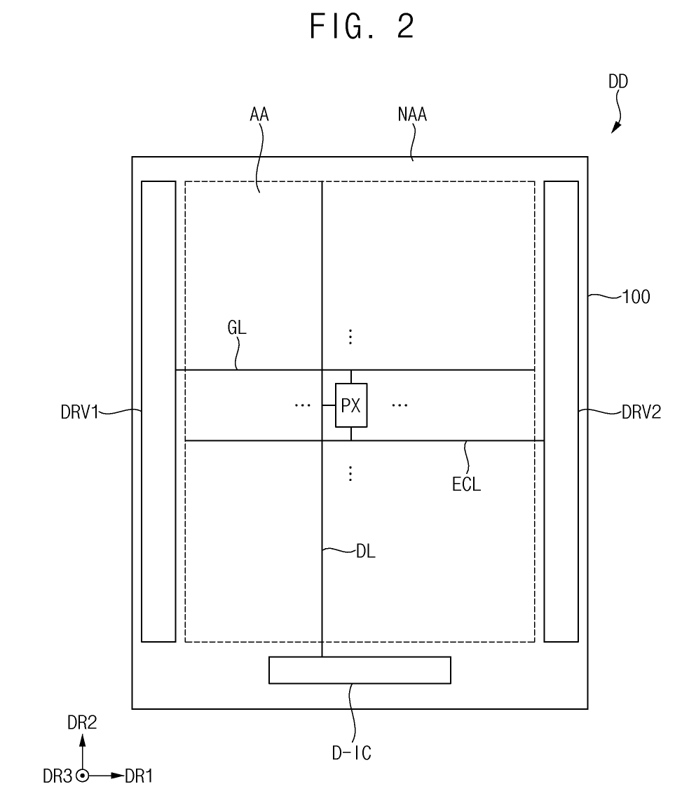

FIG. 2 is a plan view illustrating the display device of FIG. 1.

In this specification, a plane may be defined by the first direction DR1 and the second direction DR2. A direction normal to the plane, that is, a thickness direction of the display device DD may be a third direction DR3. In other words, the third direction DR3 may be perpendicular to each of the first direction DR1 and the second direction DR2. As used herein the “plan view” is a view in the third direction DR3.

Referring to FIG. 2, the display device DD may include the display panel 100, the gate lines GL, the emission lines ECL, the data lines DL, a first driver DRV1, a second driver DRV2, and a driving chip D-IC.

The display panel 100 may include a display area AA and a non-display area NAA. The display area AA may be defined as an area that displays an image by generating light or adjusting the transmittance of light provided from an external light source. The display panel 100 may include the pixels PX disposed in the display area AA. The pixels PX may be repeatedly disposed along the first direction DR1 and the second direction DR2. For example, the pixels PX may be disposed in a matrix form along the first direction DR1 and the second direction DR2.

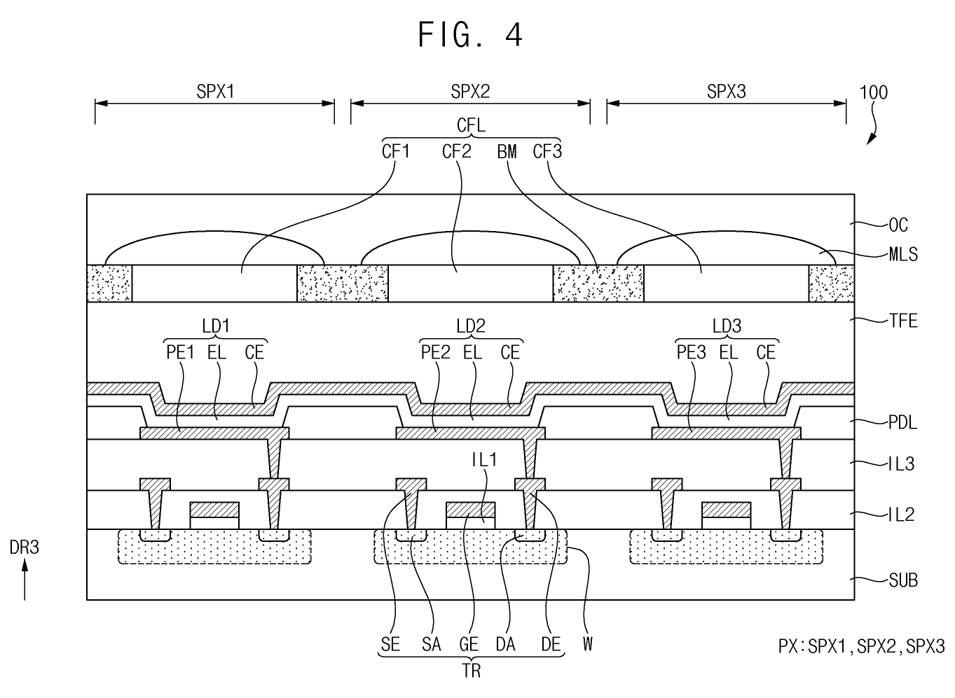

Each of the pixels PX may include a plurality of sub-pixels. For example, each of the pixels PX may include a first sub-pixel (SPX1, see FIG. 4), a second sub-pixel (SPX2, see FIG. 4), and a third sub-pixel (SPX3, see FIG. 4). Each of the first to third sub-pixels may emit light. The first to third sub-pixels may emit light of different wavelength bands. That is, the first to third sub-pixels may emit light of different colors. For example, the first sub-pixel may emit red light, the second sub-pixel may emit green light, and the third sub-pixel may emit blue light. However, the present disclosure is not necessarily limited thereto.

The non-display area NAA may be disposed around the display area AA. The non-display area NAA may surround at least a portion of the display area AA in a plan view. For example, the non-display area NAA may entirely surround the display area AA in a plan view. The non-display area NAA may be defined as an area that does not display an image.

The first driver DRV1 and the second driver DRV2 may be disposed in the non-display area NAA on the display panel 100. The first driver DRV1 and the second driver DRV2 may be spaced apart from each other. The first driver DRV1 may be disposed in the non-display area NAA adjacent to a first side of the display area AA, and the second driver DRV2 may be disposed in the non-display area NAA adjacent to a second side opposite to the first side of the display area AA. For example, the first driver DRV1 may be disposed in the non-display area NAA adjacent to a left side of the display area AA, and the second driver DRV2 may be disposed in the non-display area NAA adjacent to a right side of the display area AA. In an embodiment, the first driver DRV1 may correspond to the gate driver 300 of FIG. 1, and the second driver DRV2 may correspond to the emission driver 600 of FIG. 1, but the present disclosure is not necessarily limited thereto. In another embodiment, each of the first driver DRV1 and the second driver DRV2 may include both the gate driver 300 and the emission driver 600 of FIG. 1. In an embodiment, any one of the first driver DRV1 and the second driver DRV2 may be omitted.

The driving chip D-IC may be disposed in the non-display area NAA on the display panel 100. The driving chip D-IC may provide a driving signal to the pixels PX. For example, the driving signal may include various signals for driving the pixels PX, such as a power voltage, a data voltage, or the like. For example, the driving chip D-IC may correspond to the data driver 500 of FIG. 1.

The display device DD according to an embodiment of the present disclosure may be a display device that displays an image. For example, the display device DD may be a display device such as an organic light-emitting diode (OLED) display device, a liquid crystal display device, an organic light emitting diode on silicon (OLEDoS), a liquid crystal on silicon (LCoS), or a light emitting diode on silicon (LEDoS). In an embodiment, the display device DD may be a display device such as an OLEDoS.

For example, when the display device DD is a display device such as an OLEDoS, the display device DD may configure a head-mounted display, which is a glasses-type monitor device for virtual reality or augmented reality that is worn in the form of glasses, a helmet, or the like to form a focus point at a close distance in front of the user's eyes. However, the present disclosure is not necessarily limited thereto, and the display device DD may configure various displays in another embodiment.

FIG. 3 is a circuit diagram illustrating an example of a circuit structure of a pixel included in the display device of FIG. 1. For example, FIG. 3 is a circuit diagram of any one of the first to third sub-pixels included in each of the pixels PX.

Referring to FIG. 3, each of the pixels PX may include the first to third sub-pixels, and the first to third sub-pixels may have circuit structures that are substantially identical or symmetrical to each other. Each of the first to third sub-pixels may include a light-emitting element LD and a pixel driving circuit connected to the light-emitting element LD. The pixel driving circuit may generate a driving current, and the light-emitting element LD may generate light based on the driving current.

The pixel driving circuit may include at least one transistor and at least one capacitor. In an embodiment, the pixel driving circuit may include first to seventh transistors T1, T2, T3, T4, T5, T6, and T7 and a first capacitor C1. Each of the first to seventh transistors T1, T2, T3, T4, T5, T6, and T7 may be a metal oxide semiconductor field effect transistor (MOSFET) formed by a semiconductor process.

In an embodiment, as illustrated in FIG. 3, the fifth transistor T5 may be an n-type transistor, and the first to fourth transistors T1, T2, T3, and T4, the sixth transistor T6, and the seventh transistor T7 may be p-type transistors. However, the present disclosure is not necessarily limited thereto, and some of the first to fourth transistors T1, T2, T3, and T4, the sixth transistor T6, and the seventh transistor T7 may be p-type transistors and others may be n-type transistors in another embodiment.

For a p-type transistor, the p-type transistor may be turned off when a gate signal has a high level of voltage (e.g., a high gate voltage), and the p-type transistor may be turned on when the gate signal has a low level of voltage (e.g., a low gate voltage VGL). The high gate voltage may have a relatively high voltage level, and the low gate voltage VGL may have a relatively low voltage level. In contrast, for an n-type transistor, the n-type transistor may be turned off when a gate signal has a low level of voltage (e.g., the low gate voltage VGL), and the n-type transistor may be turned on when the gate signal has a high level of voltage (e.g., the high gate voltage).

The pixel driving circuit may be connected to first to fifth gate lines GL1, GL2, GL3, GL4, and GL5, the data lines DL, the emission lines ECL, and first to fourth voltage lines VL1, VL2, VL3, and VL4. The first gate line GL1 may transmit a first gate signal GS1. The second gate line GL2 may transmit a second gate signal GS2. The third gate line GL3 may transmit a third gate signal GS3. The fourth gate line GL4 may transmit a fourth gate signal GS4. The fifth gate line GL5 may transmit a fifth gate signal GS5. The data line DL may transmit the data voltage VDATA. The emission line ECL may transmit an emission control signal EM. The first voltage line VL1 may transmit a first power voltage ELVDD having a relatively high level of voltage. In an embodiment, the first power voltage ELVDD has a higher value than the low gate voltage VGL. The second voltage line VL2 may transmit a second power voltage ELVSS having a relatively low level of voltage. The third voltage line VL3 may transmit a first initialization voltage VINT1. The fourth voltage line VL4 may transmit a second initialization voltage VINT2.

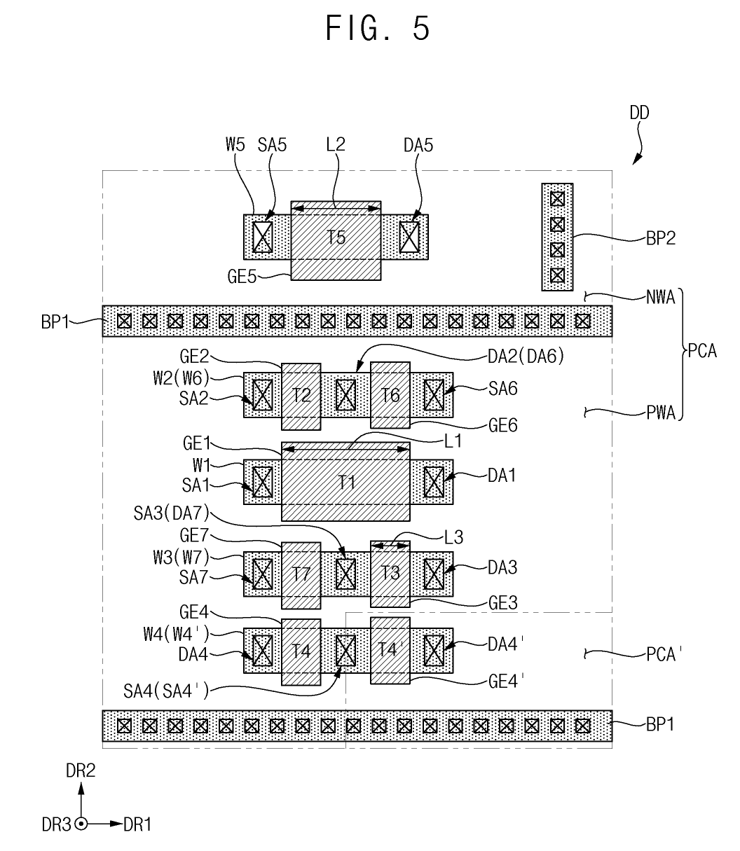

The first transistor T1 may include a gate electrode, a first electrode, and a second electrode. The gate electrode (e.g., a first gate electrode GE1 of FIG. 5) of the first transistor T1 may be connected to a first node N1. The first electrode (e.g., a source) of the first transistor T1 may receive the first power voltage ELVDD through the first voltage line VL1. The second electrode (e.g., a drain) of the first transistor T1 may be connected to a second node N2. The first transistor T1 may generate the driving current provided to the light-emitting element LD. For example, the first transistor T1 may be referred to as a “driving transistor”. The first transistor T1 may further include a body electrode. In an embodiment, the first power voltage ELVDD may be applied to the body electrode of the first transistor T1.

The second transistor T2 may include a gate electrode, a first electrode, and a second electrode. The gate electrode (e.g., a second gate electrode GE2 of FIG. 5) of the second transistor T2 may receive the first gate signal GS1 through the first gate line GL1. The first electrode (e.g., a source) of the second transistor T2 may receive the data voltage VDATA through the data line DL. The second electrode (e.g., a drain) of the second transistor T2 may be connected to a third node N3. The second transistor T2 may further include a body electrode. In an embodiment, the first power voltage ELVDD may be applied to the body electrode of the second transistor T2.

The second transistor T2 may turn on or off in response to the first gate signal GS1. While the second transistor T2 is turned on, the second transistor T2 may provide the data voltage VDATA to the third node N3. For example, the second transistor T2 may be referred to as a first switching transistor.

The third transistor T3 may include a gate electrode, a first electrode, and a second electrode. The gate electrode (e.g., a third gate electrode GE3 of FIG. 5) of the third transistor T3 may receive the second gate signal GS2 through the second gate line GL2. The first electrode (e.g., a source) of the third transistor T3 may be connected to the first node N1. The second electrode (e.g., a drain) of the third transistor T3 may be connected to the second node N2. The third transistor T3 may further include a body electrode. In an embodiment, the first power voltage ELVDD may be applied to the body electrode of the third transistor T3.

The third transistor T3 may be turned on or off in response to the second gate signal GS2. While the third transistor T3 is turned on, the third transistor T3 may diode-connect the first transistor T1. That is, the third transistor T3 may form a path to compensate for a threshold voltage of the first transistor T1. For example, the third transistor T3 may be referred to as a second switching transistor.

The fourth transistor T4 may include a gate electrode, a first electrode, and a second electrode. The gate electrode (e.g., a (4-1)-th gate electrode GE4 of FIG. 5) of the fourth transistor T4 may receive the emission control signal EM through the emission line ECL. The first electrode (e.g., a source) of the fourth transistor T4 may be connected to the second node N2. The second electrode (e.g., a drain) of the fourth transistor T4 may be connected to a fourth node N4. The fourth transistor T4 may further include a body electrode. In an embodiment, the first power voltage ELVDD may be applied to the body electrode of the fourth transistor T4.

The fourth transistor T4 may be turned on or off in response to the emission control signal EM. While the fourth transistor T4 is turned on, the fourth transistor T4 may electrically connect the second electrode of the first transistor T1 and an anode of the light-emitting element LD. Accordingly, the fourth transistor T4 may provide the driving current to the light-emitting element LD. For example, the fourth transistor T4 may be referred to as an emission control transistor.

The fifth transistor T5 may include a gate electrode, a first electrode, and a second electrode. The gate electrode (e.g., a fifth gate electrode GE5 of FIG. 5) of the fifth transistor T5 may receive the third gate signal GS3 through the third gate line GL3. The first electrode (e.g., a drain) of the fifth transistor T5 may receive the first initialization voltage VINT1 through the third voltage line VL3. The second electrode (e.g., a source) of the fifth transistor T5 may be connected to the fourth node N4. In an embodiment, the fifth transistor T5 may be an n-type transistor. The fifth transistor T5 may further include a body electrode. In an embodiment, the low gate voltage VGL having a relatively low level of voltage may be applied to the body electrode of the fifth transistor T5. However, the present disclosure is not necessarily limited thereto, and the second power voltage ELVSS may be applied to the body electrode of the fifth transistor T5 in another embodiment.

The fifth transistor T5 may be turned on or off in response to the third gate signal GS3. While the fifth transistor T5 is turned on, the fifth transistor T5 may provide the first initialization voltage VINT1 to the fourth node N4. Accordingly, the fifth transistor T5 may provide the first initialization voltage VINT1 to the anode of the light-emitting element LD to initialize a voltage of the anode. For example, the fifth transistor T5 may be referred to as an anode initialization transistor.

The sixth transistor T6 may include a gate electrode, a first electrode, and a second electrode. The gate electrode (e.g., a sixth gate electrode GE6 of FIG. 5) of the sixth transistor T6 may receive the fourth gate signal GS4 through the fourth gate line GL4. The first electrode (e.g., a source) of the sixth transistor T6 may receive the second initialization voltage VINT2 through the fourth voltage line VL4. The second electrode (e.g., a drain) of the sixth transistor T6 may be connected to the third node N3. The sixth transistor T6 may further include a body electrode. In an embodiment, the first power voltage ELVDD may be applied to the body electrode of the sixth transistor T6.

The sixth transistor T6 may be turned on or off in response to the fourth gate signal GS4. While the sixth transistor T6 is turned on, the sixth transistor T6 may provide the second initialization voltage VINT2 to the third node N3. For example, the sixth transistor T6 may be referred to as a third switching transistor.

The seventh transistor T7 may include a gate electrode, a first electrode, and a second electrode. The gate electrode (e.g., a seventh gate electrode GE7 of FIG. 5) of the seventh transistor T7 may receive the fifth gate signal GS5 through the fifth gate line GL5. The first electrode (e.g., a source) of the seventh transistor T7 may receive the second initialization voltage VINT2 through the fourth voltage line VL4. The second electrode (e.g., a drain) of the seventh transistor T7 may be connected to the first node N1. The seventh transistor T7 may further include a body electrode. In an embodiment, the first power voltage ELVDD may be applied to the body electrode of the seventh transistor T7.

The seventh transistor T7 may be turned on or off in response to the fifth gate signal GS5. While the seventh transistor T7 is turned on, the seventh transistor T7 may provide the second initialization voltage VINT2 to the first node N1. Accordingly, the seventh transistor T7 may provide the second initialization voltage VINT2 to the gate electrode of the first transistor T1 to initialize a voltage of the gate electrode of the first transistor T1. For example, the seventh transistor T7 may be referred to as a fourth switching transistor.

The first capacitor C1 may include a first electrode and a second electrode. The first electrode of the first capacitor C1 may be connected to the first node N1. The second electrode of the first capacitor C1 may be connected to the third node N3. For example, the first capacitor C1 may be referred to as a storage capacitor.

The light-emitting element LD may include the anode and a cathode. The anode of the light-emitting element LD may be connected to the fourth node N4. The cathode of the light-emitting element LD may receive the second power voltage ELVSS through the second voltage line VL2. The light-emitting element LD may generate light having a luminance corresponding to the driving current.

In FIG. 3, the pixel driving circuit is illustrated as including seven transistors and one capacitor, but the present disclosure is not necessarily limited thereto.

FIG. 4 is a cross-sectional view illustrating a display panel included in the display device of FIG. 2. For example, FIG. 4 is a cross-sectional view illustrating the pixel PX disposed in the display area AA of the display panel 100 of FIG. 2.

Referring to FIGS. 2 and 4, the display panel 100 may include a substrate SUB, a first insulating layer IL1, a second insulating layer IL2, a driving element TR, a third insulating layer IL3, a first light-emitting element LD1, a second light-emitting element LD2, a third light-emitting element LD3, a pixel defining layer PDL, an encapsulation layer TFE, a color filter layer CFL, a lens layer, and a planarization layer OC.

The pixels PX disposed in the display area AA of the display panel 100 may include a first sub-pixel SPX1, a second sub-pixel SPX2, and a third sub-pixel SPX3. The first to third sub-pixels SPX1, SPX2, and SPX3 may emit light of different wavelength bands, That is, the first to third sub-pixels SPX1, SPX2, and SPX3) may emit light of different colors. The first sub-pixel SPX1 may include the driving element TR and the first light-emitting element LD1. The second sub-pixel SPX2 may include the driving element TR and the second light-emitting element LD2. The third sub-pixel SPX3 may include the driving element TR and the third light-emitting element LD3.

The driving element TR of FIG. 4 may be a transistor connected to each of the first to third light-emitting elements LD1, LD2, and LD3. For example, the driving element TR of FIG. 4 may correspond to the fourth transistor T4 of FIG. 3.

The driving element TR may include a source area SA, a drain area DA, a gate electrode GE, a first connection electrode SE, and a second connection electrode DE. The first light-emitting element LD1 may include a first pixel electrode PE1, a light-emitting layer EL, and a common electrode CE. The second light-emitting element LD2 may include a second pixel electrode PE2, the light-emitting layer EL, and the common electrode CE. The third light-emitting element LD3 may include a third pixel electrode PE3, the light-emitting layer EL, and the common electrode CE.

The substrate SUB may be a base of the display panel 100. The substrate SUB may include a transparent material or an opaque material. The substrate SUB may include silicon, glass, quartz, plastic, or the like. These may be used alone or in combination with each other.

In an embodiment, the substrate SUB may include a silicon wafer substrate formed through a semiconductor process. For example, the substrate SUB may be a p-type silicon substrate or an n-type silicon substrate. For example, the substrate SUB may include a semiconductor material (e.g., a group IV semiconductor, a group III-V compound semiconductor, a group II-VI semiconductor, or the like). However, the present disclosure is not necessarily limited thereto.

The substrate SUB may include a well area W, and the well area W may include the source area SA, the drain area DA, and a channel area between the source area SA and the drain area DA. The well area W may be a p-type well area or an n-type well area, depending on the type of the driving element TR and the type of the substrate SUB. For example, when the driving element TR is a p-type transistor, the source area SA and the drain area DA may be an n-type source area and an n-type drain area, respectively. For example, when the driving element TR is an n-type transistor, the source area SA and the drain area DA may be a p-type source area and a p-type drain area, respectively.

The first insulating layer IL1 may be disposed on the substrate SUB. The first insulating layer IL1 may at least partially overlap the well area W. The first insulating layer IL1 may include an inorganic insulating material. Examples of the inorganic insulating material that may be used as the first insulating layer IL1 may include silicon oxide (SiOₓ), silicon nitride (SiNₓ), silicon oxynitride (SiOₓN_{y}), or the like. These may be used alone or in combination with each other.

The gate electrode GE may be disposed on the first insulating layer IL1. The gate electrode GE may overlap the first insulating layer IL1 and the well area W in a plan view. The gate electrode GE may include a conductive material such as a metal, an alloy, a conductive metal oxide, a conductive metal nitride, a transparent conductive oxide, or the like. Examples of the conductive material may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The second insulating layer IL2 may be disposed on the substrate SUB. The second insulating layer IL2 may cover the gate electrode GE. The second insulating layer IL2 may include an inorganic insulating material. Examples of the inorganic insulating material that may be used as the second insulating layer IL2 may include silicon oxide (SiOₓ), silicon nitride (SiNₓ), silicon oxynitride (SiOₓN_{y}), or the like. These may be used alone or in combination with each other.

The first connection electrode SE and the second connection electrode DE may be disposed on the second insulating layer IL2. The first connection electrode SE may be connected to the source area SA through a contact hole penetrating a lower insulating layer (e.g., the second insulating layer IL2). The second connection electrode DE may be connected to the drain area DA through a contact hole penetrating a lower insulating layer (e.g., the second insulating layer IL2). Each of the first connection electrode SE and the second connection electrode DE may include a conductive material such as a metal, an alloy, a conductive metal oxide, a conductive metal nitride, a transparent conductive oxide, or the like. These may be used alone or in combination with each other.

Accordingly, the driving element TR including the source area SA, the drain area DA, the gate electrode GE, the first connection electrode SE, and the second connection electrode DE may be formed on the substrate SUB.

The third insulating layer IL3 may be disposed on the second insulating layer IL2. The third insulating layer IL3 may cover the first connection electrode SE and the second connection electrode DE. The third insulating layer IL3 may include an organic insulating material. Examples of the organic insulating material that may be used as the third insulating layer IL3 may include a polyacryl-based resin, a polyimide-based resin, a polyamide-based resin, a siloxane-based resin, an acrylic-based resin, an epoxy-based resin, or the like. These may be used alone or in combination with each other.

The first pixel electrode PE1, the second pixel electrode PE2, and the third pixel electrode PE3 may be disposed on the third insulating layer IL3. The first to third pixel electrodes PE1, PE2, and PE3 may be spaced apart from each other. Each of the first to third pixel electrodes PE1, PE2, and PE3 may be electrically connected to the driving element TR. For example, each of the first to third pixel electrodes PE1, PE2, and PE3 may be connected to the second connection electrode DE (or the first connection electrode SE) through a contact hole penetrating a lower insulating layer (e.g., the third insulating layer IL3). Each of the first to third pixel electrodes PE1, PE2, and PE3 may include a conductive material such as a metal, an alloy, a conductive metal oxide, a conductive metal nitride, a transparent conductive oxide, or the like. These may be used alone or in combination with each other.

For example, the first pixel electrode PE1 may operate as an anode of the first light-emitting element LD1, the second pixel electrode PE2 may operate as an anode of the second light-emitting element LD2, and the third pixel electrode PE3 may operate as an anode of the third light-emitting element LD3.

The pixel defining layer PDL may be disposed on the third insulating layer IL3. The pixel defining layer PDL may cover an edge of each of the first to third pixel electrodes PE1, PE2, and PE3. In addition, the pixel defining layer PDL may define a pixel opening exposing an upper surface of each of the first to third pixel electrodes PE1, PE2, and PE3. The pixel defining layer PDL may include an organic insulating material and/or an inorganic insulating material.

The light-emitting layer EL may be disposed on the first to third pixel electrodes PE1, PE2, and PE3 and the pixel defining layer PDL. The light-emitting layer EL may include an organic material that emits light of a color (e.g., a preset color). In addition, the light-emitting layer EL may include at least one of a hole injection layer, a hole transport layer, an electron injection layer, and an electron transport layer.

In an embodiment, as illustrated in FIG. 4, the light-emitting layer EL of the first sub-pixel SPX1, the light-emitting layer EL of the second sub-pixel SPX2, and the light-emitting layer EL of the third sub-pixel SPX3 may be integrally formed. That is, the light-emitting layer EL may continuously extend over the first to the third sub-pixels SPX1, SPX2, and SPX3. In this case, the light-emitting layer EL may include an organic material that emits white light. However, the present disclosure is not necessarily limited thereto.

In an embodiment, the light-emitting layer EL may be independently disposed on each of the first to third sub-pixels SPX1, SPX2, and SPX3. That is, a first light-emitting layer of the first sub-pixel SPX1, a second light-emitting layer of the second sub-pixel SPX2, and a third light-emitting layer of the third sub-pixel SPX3 may be spaced apart from each other. In this case, the first light-emitting layer may include an organic material that emits red light, the second light-emitting layer may include an organic material that emits green light, and the third light-emitting layer may include an organic material that emits blue light, but the present disclosure is not necessarily limited thereto.

The common electrode CE may be disposed on the light-emitting layer EL. The common electrode CE may continuously extend over the first to third sub-pixels SPX1, SPX2, and SPX3. For example, the common electrode CE may be disposed along the profile of the light-emitting layer EL with a substantially uniform thickness. The common electrode CE may include a conductive material such as a metal, an alloy, a conductive metal oxide, a conductive metal nitride, a transparent conductive oxide, or the like. These may be used alone or in combination with each other. For example, the common electrode CE may operate as a cathode of the first to third light-emitting elements LD1, LD2, and LD3.

Accordingly, the first light-emitting element LD1 including the first pixel electrode PE1, the light-emitting layer EL, and the common electrode CE may be disposed on the substrate SUB. The driving element TR and the first light-emitting element LD1 may correspond to the first sub-pixel SPX1. The first sub-pixel SPX1 may define a first light-emitting area from which light is emitted.

In addition, the second light-emitting element LD2 including the second pixel electrode PE2, the light-emitting layer EL, and the common electrode CE may be disposed on the substrate SUB. The driving element TR and the second light-emitting element LD2 may correspond to the second sub-pixel SPX2. The second sub-pixel SPX2 may define a second light-emitting area from which light is emitted.

In addition, the third light-emitting element LD3 including the third pixel electrode PE3, the light-emitting layer EL, and the common electrode CE may be disposed on the substrate SUB. The driving element TR and the third light-emitting element LD3 may correspond to the third sub-pixel SPX3. The third sub-pixel SPX3 may define a third light-emitting area from which light is emitted. Light of different colors may be emitted from the first to third emission areas.

The encapsulation layer TFE may be disposed on the common electrode CE. The encapsulation layer TFE may prevent impurities, moisture, or the like from penetrating into the first to third light-emitting elements LD1, LD2, and LD3 from the outside. The encapsulation layer TFE may include at least one inorganic encapsulation layer and at least one organic encapsulation layer. For example, the inorganic encapsulation layer may include silicon oxide (SiOₓ), silicon nitride (SiNₓ), silicon oxynitride (SiOₓN_{y}), or the like. These may be used alone or in combination with each other. For example, the organic encapsulation layer may include a polymer cured material such as polyacrylate. In an embodiment, the encapsulation layer TFE may include a first inorganic encapsulation layer, an organic encapsulation layer, and a second inorganic encapsulation layer that are sequentially stacked along the third direction DR3, but the present disclosure is not necessarily limited thereto.

The color filter layer CFL may be disposed on the encapsulation layer TFE. The color filter layer CFL may include a first color filter CF1, a second color filter CF2, and a third color filter CF3 that transmit light of different colors. In an embodiment, the color filter layer CFL may further include a light blocking pattern BM disposed between the first to third color filters CF1, CF2, and CF3.

The first color filter CF1 may be disposed in the first light-emitting area, the second color filter CF2 may be disposed in the second light-emitting area, and the third color filter CF3 may be disposed in the third light-emitting area. Each of the first to third color filters CF1, CF2, and CF3 may selectively transmit light of a specific wavelength, and may absorb light of other wavelengths. For example, the first color filter CF1 may transmit red light, the second color filter CF2 may transmit green light, and the third color filter CF3 may transmit blue light. Accordingly, red light may be emitted from the first light-emitting area, green light may be emitted from the second light-emitting area, and blue light may be emitted from the third light-emitting area. However, the present disclosure is not necessarily limited thereto.

The light blocking pattern BM may be disposed between the first to third color filters CF1, CF2, and CF3. That is, the light blocking pattern BM may be disposed between the first color filter CF1 and the second color filter CF2, between the second color filter CF2 and the third color filter CF3, and between the first color filter CF1 and the third color filter CF3. The light blocking pattern BM may include a light blocking material. Examples of the light blocking material may include a black pigment, a black dye, carbon black, or the like. Accordingly, the light blocking pattern BM may block light incident on the light blocking pattern BM. As a result, the light blocking pattern BM may prevent color mixing between the first to third light-emitting areas.

The lens layer may be disposed on the color filter layer CFL and may include micro lenses MLS. The micro lenses MLS may overlap the first color filter CF1, the second color filter CF2, and the third color filter CF3, respectively, in a plan view. The micro lenses MLS may improve light extraction efficiency. Each of the micro lenses MLS may have a refractive index (e.g., a predetermined refractive index). For example, each of the micro lenses MLS may have a refractive index greater than or equal to about 1.5 and less than or equal to about 1.7, but the present disclosure is not necessarily limited thereto.

The planarization layer OC may be disposed on the color filter layer CFL and the micro lenses MLS. The planarization layer OC may include an organic material or an inorganic material. The planarization layer OC may planarize step differences caused by components disposed under the planarization layer OC (e.g., the color filter layer CFL, the micro lenses MLS, or the like).

FIG. 5 is a layout view illustrating an example of a pixel included in the display device of FIG. 1. For example, FIG. 5 is a layout view illustrating an example of the pixel driving circuit included in the pixel PX described above with reference to FIG. 3.

Referring to FIGS. 3 and 5, the pixel PX included in the display device DD may include the first to third sub-pixels (SPX1, SPX2, and SPX3, see FIG. 4), and the first to third sub-pixels may have circuit structures that are substantially identical or symmetrical to each other. Each of the first to third sub-pixels may include a pixel driving circuit, and the pixel driving circuit may include first to seventh transistors T1, T2, T3, T4, T5, T6, and T7, a first body pattern BP1 and a second body pattern BP2 disposed in a pixel circuit area PCA. The first to seventh transistors T1, T2, T3, T4, T5, T6, and T7 of FIG. 5 may correspond to the first to seventh transistors T1, T2, T3, T4, T5, T6, and T7 of FIG. 3, respectively.

The pixel circuit area PCA may be an area in which the pixel driving circuit included in any one of the first to third sub-pixels is disposed. That is, the first to third sub-pixels may include substantially identical or symmetrical pixel circuit areas PCA. The pixel circuit area PCA of an N-th row may be adjacent to a pixel circuit area PCA` of a (N+1)-th row. Here, the pixel circuit area PCA of the N-th row may be defined as an area in which the pixel driving circuit included in a sub-pixel disposed in an N-th pixel row is disposed, and the pixel circuit area PCA` of the (N+1)-th row may be defined as an area in which the pixel driving circuit included in a sub-pixel disposed in a (N+1)-th pixel row is disposed. In FIG. 5, for convenience of description, only a fourth transistor (T4`, hereinafter referred to as a fourth transistor of the (N+1)-th row) of the pixel driving circuit disposed in the (N+1)-th pixel row is illustrated.

A first well area W1 and a first gate electrode GE1 may define the first transistor T1. The first gate electrode GE1 may at least partially overlap the first well area W1 in a plan view. The first well area W1 may have a width in the second direction DR2 and may extend in the first direction DR1.

The first well area W1 may include a first source area SA1 and a first drain area DA1. The first source area SA1 may be an area where the first well area W1 and a first connection electrode (e.g., the first connection electrode SE of FIG. 4) of the first transistor T1 connect. The first connection electrode of the first transistor T1 may receive the first power voltage ELVDD. The first drain area DA1 may be an area where the first well area W1 and a second connection electrode (e.g., the second connection electrode DE of FIG. 4) of the first transistor T1 connect. The first source area SA1 and the first drain area DA1 may be spaced apart from each other by the first gate electrode GE1 in a plan view.

A second well area W2 and a second gate electrode GE2 may define the second transistor T2. The second gate electrode GE2 may at least partially overlap the second well area W2 in a plan view. The second gate electrode GE2 may receive the first gate signal GS1. The second well area W2 may have a width in the second direction DR2 and may extend in the first direction DR1. For example, the second well area W2 may be spaced apart from the first well area W1 in the second direction DR2.

The second well area W2 may include a second source area SA2 and a second drain area DA2. The second source area SA2 may be an area where the second well area W2 and a first connection electrode of the second transistor T2 connect. The first connection electrode of the second transistor T2 may receive the data voltage VDATA. The second drain area DA2 may be an area where the second well area W2 and a second connection electrode of the second transistor T2 connect. The second source area SA2 and the second drain area DA2 may be spaced apart from each other by the second gate electrode GE2 in a plan view.

A sixth well area W6 and a sixth gate electrode GE6 may define the sixth transistor T6. The sixth gate electrode GE6 may at least partially overlap the sixth well area W6 in a plan view. The sixth gate electrode GE6 may receive the fourth gate signal GS4. The sixth well area W6 may have a width in the second direction DR2 and may extend in the first direction DR1. For example, the sixth well area W6 may be spaced apart from the first well area W1 in the second direction DR2.

The sixth well area W6 may include a sixth source area SA6 and a sixth drain area DA6. The sixth source area SA6 may be an area where the sixth well area W6 and a first connection electrode of the sixth transistor T6 connect. The first connection electrode of the sixth transistor T6 may receive the second initialization voltage VINT2. The sixth drain area DA6 may be an area where the sixth well area W6 and a second connection electrode of the sixth transistor T6 connect. The sixth source area SA6 and the sixth drain area DA6 may be spaced apart from each other by the sixth gate electrode GE6 in a plan view.

In an embodiment, the sixth well area W6 may extend from the second well area W2. The sixth well area W6 may be integrally formed with the second well area W2.

In an embodiment, the sixth drain area DA6 may be substantially identical to the second drain area DA2. That is, an area where the sixth well area W6 and the second connection electrode of the sixth transistor T6 connect may be an area where the second well area W2 and the second connection electrode of the second transistor T2 connect. That is, the second transistor T2 and the sixth transistor T6 may share a well area (e.g., the second well area W2 or the sixth well area W6) and a connection area (e.g., the second drain area DA2 or the sixth drain area DA6).

In an embodiment, the second gate electrode GE2 and the sixth gate electrode GE6 may be spaced apart from each other in the first direction DR1. The second gate electrode GE2 and the sixth gate electrode GE6 may be spaced apart from the first gate electrode GE1 in the second direction DR2.

A third well area W3 and a third gate electrode GE3 may define the third transistor T3. The third gate electrode GE3 may at least partially overlap the third well area W3 in a plan view. The third gate electrode GE3 may receive the second gate signal GS2. The third well area W3 may have a width in the second direction DR2 and may extend in the first direction DR1. For example, the third well area W3 may be spaced from the first well area W1 in an opposite direction of the second direction DR2.

The third well area W3 may include a third source area SA3 and a third drain area DA3. The third source area SA3 may be an area where the third well area W3 and a first connection electrode of the third transistor T3 connect. The third drain area DA3 may be an area where the third well area W3 and a second connection electrode of the third transistor T3 connect. The third source area SA3 and the third drain area DA3 may be spaced apart from each other by the third gate electrode GE3 in a plan view.

A seventh well area W7 and a seventh gate electrode GE7 may define the seventh transistor T7. The seventh gate electrode GE7 may at least partially overlap the seventh well area W7 in a plan view. The seventh gate electrode GE7 may receive the fifth gate signal GS5. The seventh well area W7 may have a width in the second direction DR2 and may extend in the first direction DR1. For example, the seventh well area W7 may be spaced from the first well area W1 in the opposite direction of the second direction DR2.

The seventh well area W7 may include a seventh source area SA7 and a seventh drain area DA7. The seventh source area SA7 may be an area where the seventh well area W7 and a first connection electrode of the seventh transistor T7 connect. The first connection electrode of the seventh transistor T7 may receive the second initialization voltage VINT2. The seventh drain area DA7 may be an area where the seventh well area W7 and a second connection electrode of the seventh transistor T7 connect. The seventh source area SA7 and the seventh drain area DA7 may be spaced apart from each other by the seventh gate electrode GE7 in a plan view.

In an embodiment, the seventh well area W7 may extend from the third well area W3. The seventh well area W7 may be integrally formed with the third well area W3.

In an embodiment, the seventh drain area DA7 may be substantially identical to the third source area SA3. That is, an area where the seventh well area W7 and the second connection electrode of the seventh transistor T7 connect may be an area where the third well area W3 and the first connection electrode of the third transistor T3 connect. That is, the third transistor T3 and the seventh transistor T7 may share a well area (e.g., the third well area W3 or the seventh well area W7) and a connection area (e.g., the third source area SA3 or the seventh drain area DA7).

In an embodiment, the third gate electrode GE3 and the seventh gate electrode GE7 may be spaced apart from each other in the first direction DR1. The third gate electrode GE3 and the seventh gate electrode GE7 may be spaced apart from the first gate electrode GE1 in the opposite direction of the second direction DR2.

Although it is illustrated in FIG. 5 that the second transistor T2 and the sixth transistor T6 are disposed at an upper portion of the first transistor T1, and the third transistor T3 and the seventh transistor T7 are disposed at a lower portion of the first transistor T1, the present disclosure is not necessarily limited thereto. In another embodiment, the second transistor T2 and the sixth transistor T6 may be disposed at the lower portion of the first transistor T1, and the third transistor T3 and the seventh transistor T7 may be disposed at the upper portion of the first transistor T1.

In addition, although it is illustrated in FIG. 5 that the second transistor T2 is adjacent to a left side of the second well area W2 (or the sixth well area W6), and the sixth transistor T6 is adjacent to a right side of the second well area W2 (or the sixth well area W6), the present disclosure is not necessarily limited thereto. In another embodiment, the second transistor T2 may be adjacent to the right side of the second well area W2 (or the sixth well area W6), and the sixth transistor T6 may be adjacent to the left side of the second well area W2 (or the sixth well area W6).

In addition, although it is illustrated in FIG. 5 that the seventh transistor T7 is adjacent to a left side of the third well area W3 (or the seventh well area W7), and the third transistor T3 is adjacent to a right side of the third well area W3 (or the seventh well area W7), the present disclosure is not necessarily limited thereto. In another embodiment, the seventh transistor T7 may be adjacent to the right side of the third well area W3 (or the seventh well area W7), and the third transistor T3 may be adjacent to the left side of the third well area W3 (or the seventh well area W7).

A (4-1)-th well area W4 and a (4-1)-th gate electrode GE4 may define the fourth transistor T4. The (4-1)-th gate electrode GE4 may at least partially overlap the (4-1)-th well area W4 in a plan view. The (4-1)-th gate electrode GE4 may receive the emission control signal EM. The (4-1)-th well area W4 may have a width in the second direction DR2 and may extend in the first direction DR1. For example, the (4-1)-th well area W4 may be spaced apart from the first well area W1 in the opposite direction of the second direction DR2. In addition, the (4-1)-th well area W4 may be spaced apart from the third well area W3 (or the seventh well area W7) in the opposite direction of the second direction DR2.

The (4-1)-th well area W4 may include a (4-1)-th source area SA4 and a (4-1)-th drain area DA4. The (4-1)-th source area SA4 may be an area where the (4-1)-th well area W4 and a first connection electrode of the fourth transistor T4 connect. The (4-1)-th drain area DA4 may be an area where the (4-1)-th well area W4 and a second connection electrode of the fourth transistor T4 connect. The (4-1)-th source area SA4 and the (4-1)-th drain area DA4 may be spaced apart from each other by the (4-1)-th gate electrode GE4 in a plan view.

A (4-2)-th well area W4` and a (4-2)-th gate electrode GE4` may define the fourth transistor T4` of the (N+1)-th row. The (4-2)-th gate electrode GE4` may at least partially overlap the (4-2)-th well area W4` in a plan view. The (4-2)-th well area W4` may have a width in the second direction DR2 and may extend in the first direction DR1 . For example, the (4-2)-th well area W4` may be spaced from the first well area W1 in the opposite direction of the second direction DR2. In addition, the (4-2)-th well area W4` may be spaced apart from the third well area W3 (or the seventh well area W7) in the opposite direction of the second direction DR2.

The (4-2)-th well area W4` may include a (4-2)-th source area SA4` and a (4-2)-th drain area DA4`. The (4-2)-th source area SA4` may be an area where the (4-2)-th well area W4` and a first connection electrode of the fourth transistor T4` of the (N+1)-th row connect. The (4-2)-th drain area DA4` may be an area where the (4-2)-th well area W4` and a second connection electrode of the fourth transistor T4` of the (N+1)-th row connect. The (4-2)-th source area SA4` and the (4-2)-th drain area DA4` may be spaced apart from each other by the (4-2)-th gate electrode GE4` in a plan view.

In an embodiment, the (4-2)-th well area W4` may extend from the (4-1)-th well area W4. The (4-2)-th well area W4` may be integrally formed with the (4-1)-th well area W4. The (4-1)-th well area W4 (or the (4-2)-th well area W4`) may be disposed in the pixel circuit area PCA of the N-th row and the pixel circuit area PCA` of the (N+1)-th row.

In an embodiment, the (4-2)-th source area SA4` may be substantially identical to the (4-1)-th source area SA4. That is, an area where the (4-2)-th well area W4` and the first connection electrode of the fourth transistor T4` of the (N+1)-th row connect may be an area where the (4-1)-th well area W4 and the first connection electrode of the fourth transistor T4 of the N-th row connect. That is, the fourth transistor T4 of the N-th row and the fourth transistor T4` of the (N+1)-th row may share a well area (e.g., the (4-1)-th well area W4 or the (4-2)-th well area W4`) and a connection area (e.g., the (4-1)-th source area SA4 or the (4-2)-th source area SA4`).

In an embodiment, the (4-1)-th gate electrode GE4 and the (4-2)-th gate electrode GE4` may be spaced apart from each other in the first direction DR1. The (4-1)-th gate electrode GE4 and the (4-2)-th gate electrode GE4` may be spaced apart from the first gate electrode GE1 in the opposite direction of the second direction DR2.

A fifth well area W5 and a fifth gate electrode GE5 may define the fifth transistor T5. The fifth gate electrode GE5 may at least partially overlap the fifth well area W5 in a plan view. The fifth gate electrode GE5 may receive the third gate signal GS3. The fifth well area W5 may have a width in the second direction DR2 and may extend in the first direction DR1. For example, the fifth well area W5 may be spaced apart from the first well area W1 in the second direction DR2. In addition, the fifth well area W5 may be spaced apart from the second well area W2 (or the sixth well area W6) in the second direction DR2.

The fifth well area W5 may include a fifth source area SA5 and a fifth drain area DA5. The fifth source area SA5 may be an area where the fifth well area W5 and a second connection electrode of the fifth transistor T5 connect. The fifth drain area DA5 may be an area where the fifth well area W5 and a first connection electrode of the fifth transistor T5 connect. The first connection electrode of the fifth transistor T5 may receive the first initialization voltage VINT1. The fifth source area SA5 and the fifth drain area DA5 may be spaced apart from each other by the fifth gate electrode GE5 in a plan view.

In an embodiment, each of the first to fourth transistors T1, T2, T3, and T4, the sixth transistor T6, and the seventh transistor T7 may be a p-type transistor, and the fifth transistor T5 may be an n-type transistor. In this case, each of the first source area SA1, the second source area SA2, the third source area SA3, the (4-1)-th source area SA4, the sixth source area SA6, and the seventh source area SA7 may be an n-type source area, and each of the first drain area DA1, the second drain area DA2, the third drain area DA3, the (4-1)-th drain area DA4, the sixth drain area DA6, and the seventh drain area DA7 may be an n-type drain area. The fifth source area SA5 may be a p-type source area, and the fifth drain area DA5 may be a p-type drain area.

As described above, the first transistor T1 may be referred to as a driving transistor, the fourth transistor T4 may be referred to as an emission control transistor, and the fifth transistor T5 may be referred to as an anode initialization transistor. The second transistor T2 may be referred to as a first switching transistor, the third transistor T3 may be referred to as a second switching transistor, the sixth transistor T6 may be referred to as a third switching transistor, and the seventh transistor T7 may be referred to as a fourth switching transistor.

In an embodiment, a first length L1 of a channel of the first transistor T1 may be greater than a second length L2 of a channel of the fifth transistor T5, and the second length L2 of the channel of the fifth transistor T5 may be greater than a third length L3 of a channel of each of the second transistor T2, the third transistor T3, the fourth transistor T4, the sixth transistor T6, and the seventh transistor T7. That is, the second length L2 of the channel of the fifth transistor T5, which is an n-type transistor, may be greater than the third length L3 of the channel of each of the switching transistors T2, T3, T4, T6, and T7 excluding the driving transistor among the p-type transistors. Here, the length of the channel of the transistor may correspond to a length in the first direction DR1 of the gate electrode overlapping the well area in a plan view between the source area and the drain area.

By designing the second length L2 of the channel of the fifth transistor T5 to be relatively greater than the third length L3 of the channel of each of the switching transistors T2, T3, T4, T6, and T7, a leakage current generated in the fifth transistor T5 while the fifth transistor T5 is turned off may be relatively reduced. Accordingly, the power consumption of the display device DD may be relatively reduced.

The pixel circuit area PCA may include a first area PWA and a second area NWA. The first area PWA may be defined as an area where the p-type transistors are disposed on the substrate (SUB, see FIG. 4), and the second area NWA may be defined as an area where the n-type transistor is disposed on the substrate. The first to fourth transistors T1, T2, T3, and T4, the sixth transistor T6, and the seventh transistor T7 may be formed in the first area PWA on the substrate, and the fifth transistor T5 may be formed in the second area NWA on the substrate.

The first body pattern BP1 may have a width in the second direction DR2 and may extend in the first direction DR1. In an embodiment, the first body pattern BP1 may define a boundary between the first area PWA and the second area NWA. That is, the fifth transistor T5 may be spaced apart from the first to fourth transistors T1, T2, T3, and T4, the sixth transistor T6, and the seventh transistor T7 by the first body pattern BP1 in a plan view.

In an embodiment, the first power voltage ELVDD may be applied to the first body pattern BP1. As the first power voltage ELVDD is applied to the first body pattern BP1, the substrate SUB may have the first power voltage ELVDD in the first area PWA, and the first power voltage ELVDD may be applied to the body electrode of each of the first to fourth transistors T1, T2, T3, and T4, the sixth transistor T6, and the seventh transistor T7.

The second body pattern BP2 may have a width in the first direction DR1 and may extend in the second direction DR2. The second body pattern BP2 may be disposed in the second area NWA on the substrate. The second body pattern BP2 may be spaced apart from the fifth transistor T5 (specifically, the fifth well area W5) in the first direction DR1. In an embodiment, a longitudinal direction of the second body pattern BP2 (e.g., the second direction DR2) may be perpendicular to a longitudinal direction of the fifth well area W5 (e.g., the first direction DR1). That is, the second body pattern BP2 may extend in a direction perpendicular to the longitudinal direction of the fifth well area W5. In other words, the second body pattern BP2 may extend in a direction parallel to a width direction of the fifth well area W5. Accordingly, a space between the second body pattern BP2 and the fifth well area W5 may be relatively more secured within the limited area of the pixel circuit area PCA, and the second length L2 of the channel of the fifth transistor T5 may be designed to be relatively greater.

In an embodiment, the low gate voltage VGL may be applied to the second body pattern BP2. As the low gate voltage VGL is applied to the second body pattern BP2, the substrate SUB may have the low gate voltage VGL in the second area NWA, and the low gate voltage VGL may be applied to the body electrode of the fifth transistor T5.

FIG. 6 is a block diagram of an electronic device according to an embodiment of the present disclosure.

Referring to FIG. 6, an electronic device 10 according to an embodiment may include a display module 11, a processor 12, a memory 13, and a power module 14. The display device according to an embodiment may be applied to a variety of electronic devices. The electronic device 10 according to an embodiment may include the display device described above, and may further include modules or devices having other additional functions in addition to the display device.

The processor 12 may include at least one of a central processing unit (CPU), an application processor (AP), a graphic processing unit (GPU), a communication processor (CP), an image signal processor (ISP), and a controller.

The memory 13 may store data information required for operation of the processor 12 or the display module 11. When the processor 12 executes an application stored in the memory 13, an image data signal and/or an input control signal may be transmitted to the display module 11, and the display module 11 may process the received signals and may output image information through a display screen.

The power module 14 may include a power supply module, such as a power adapter or a battery device, etc., and a power conversion module that converts power supplied by the power supply module to generate the power required for operation of the electronic device 10. That is, the power module 14 may provide power to the display device according to the embodiments described above.

At least one of the components of the electronic device 10 described above may be included in the display device according to the embodiments described above. In addition, some of the individual modules that are functionally included in one module may be included in the display device and others may be provided separately from the display device. For example, the display device may include the display module 11, and the processor 12, the memory 13, and the power module 14 may be provided in the form of other devices in the electronic device 10 other than the display device.

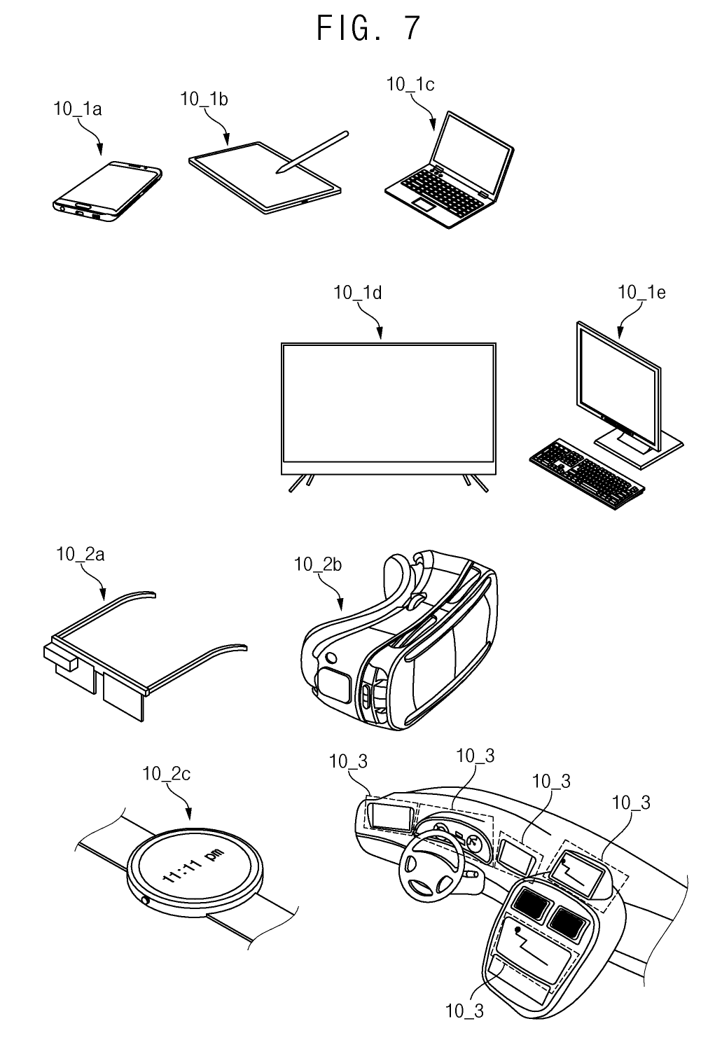

FIG. 7 is a schematic view of an electronic device according to various embodiments.

Referring to FIG. 7, various electronic devices to which a display device according to the embodiments is applied may include image display electronic devices such as a smartphones 10_1a, a tablet PC 10_1b, a laptop 10_1c, a television 10_1d, a desk monitor 10_1e, or the like, wearable electronic devices including display modules such as a smart glasses 10_2a, a head-mounted display 10_2b, and a smart watch 10_2c, or the like, and vehicle electronic devices 10_3 including display modules such as a CID (center information display) which may be disposed on a instrument panel, a center fascia, and a dashboard of an automobile and a room mirror display, or the like.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. A display device comprising:
a substrate;
a light-emitting element, which is disposed on the substrate and generates light based on a driving current; and
a pixel driving circuit, which is disposed on the substrate and drives the light-emitting element,
wherein the pixel driving circuit comprises:
a driving transistor, which generates the driving current;
at least one switching transistor electrically connected to the driving transistor; and
an anode initialization transistor, which receives a first initialization voltage, initializes a voltage of an anode of the light-emitting element, and is an n-type transistor, and
wherein a first length of a channel of the driving transistor is greater than a second length of a channel of the anode initialization transistor, and the second length of the channel of the anode initialization transistor is greater than a third length of a channel of each of the at least one switching transistor.

2. The display device of claim 1, wherein the substrate comprises:
a first area in which the driving transistor and the at least one switching transistor are disposed; and
a second area in which the anode initialization transistor is disposed.

3. The display device of claim 2,
wherein the pixel driving circuit further comprises a first body pattern to which a first power voltage having a relatively high level of voltage is applied, and
wherein the first body pattern extends in a first direction and defines a boundary between the first area and the second area.

4. The display device of claim 3,
wherein the pixel driving circuit further comprises a second body pattern to which a low gate voltage having a relatively low level of voltage is applied, and
wherein the second body pattern is disposed in the second area on the substrate, has a width in the first direction, and extends in a second direction intersecting the first direction.

5. The display device of claim 4,
wherein the anode initialization transistor comprises a well area comprising a source area and a drain area, and
wherein the second body pattern extends in a direction parallel to a width direction of the well area of the anode initialization transistor.

6. The display device of claim 1,
wherein each of the driving transistor, the anode initialization transistor, and the at least one switching transistor comprises a body electrode,
wherein a voltage having a relatively high voltage level is applied to the body electrode of the driving transistor and the body electrode of the at least one switching transistor, and
wherein a voltage having a relatively low voltage level is applied to the body electrode of the anode initialization transistor.

7. The display device of claim 6,
wherein a first power voltage is applied to the body electrode of the driving transistor and the body electrode and the at least one switching transistor, and
wherein a low gate voltage is applied to the body electrode of the anode initialization transistor.

8. The display device of claim 1,
wherein the driving transistor comprises a first electrode, which receives a first power voltage, a gate electrode connected to a first node, and a second electrode connected to a second node, and
wherein the at least one switching transistor comprises:
a first switching transistor comprising a first electrode, which receives a data voltage, a gate electrode, which receives a first gate signal, and a second electrode connected to a third node; and
an emission control transistor comprising a first electrode connected to the second node, a gate electrode, which receives an emission control signal, and a second electrode connected to a fourth node, the emission control transistor electrically connecting the driving transistor and the light-emitting element in response to the emission control signal.

9. The display device of claim 8, comprising:
a plurality of sub-pixels, which are repeatedly disposed on the substrate along a first direction and a second direction intersecting the first direction, each of the plurality of sub-pixels comprising the light-emitting element and the pixel driving circuit.

10. The display device of claim 9,
wherein the emission control transistor comprises a well area comprising a source area and a drain area, and
wherein the well area of the emission control transistor of the pixel driving circuit included in a sub-pixel disposed in an N-th row is integrally formed with the well area of the emission control transistor of the pixel driving circuit included in a sub-pixel disposed in a (N+1)-th row adjacent to the N-th row in the second direction,
wherein N is a natural number.

11. The display device of claim 8,
wherein the anode initialization transistor provides the first initialization voltage to the fourth node in response to a third gate signal, and
wherein the at least one switching transistor further comprises:
a second switching transistor comprising a first electrode connected to the first node, a gate electrode, which receives a second gate signal, and a second electrode connected to the second node, the second switching transistor diode-connecting the driving transistor in response to the second gate signal;
a third switching transistor comprising a first electrode, which receives a second initialization voltage different from the first initialization voltage, a gate electrode, which receives a fourth gate signal, and a second electrode connected to the third node; and
a fourth switching transistor comprising a first electrode, which receives the second initialization voltage, a gate electrode, which receives a fifth gate signal, and a second electrode connected to the gate electrode of the driving transistor through the first node.

12. The display device of claim 11,
wherein each of the first switching transistor and the third switching transistor comprises a well area comprising a source area and a drain area, and
wherein the well area of the first switching transistor and the well area of the third switching transistor are integrally formed.

13. The display device of claim 11,
wherein each of the second switching transistor and the fourth switching transistor comprises a well area comprising a source area and a drain area, and
wherein the well area of the second switching transistor and the well area of the fourth switching transistor are integrally formed.

14. The display device of claim 11, wherein each of the first switching transistor, the second switching transistor, the emission control transistor, the third switching transistor, and the fourth switching transistor is a p-type transistor.

15. The display device of claim 11, wherein the pixel driving circuit further comprises:
a first capacitor comprising a first electrode connected to the gate electrode of the driving transistor through the first node and a second electrode connected to the first switching transistor through the third node.

16. The display device of claim 1, wherein the substrate comprises a silicon wafer substrate.

17. An electronic device comprising:
a display device comprising a substrate, a light-emitting element, which is disposed on the substrate and generates light based on a driving current, and a pixel driving circuit, which is disposed on the substrate and drives the light-emitting element; and
a processor, which transmits an image data signal and an input control signal to the display device,
wherein the pixel driving circuit comprises:
a driving transistor, which generates the driving current;
at least one switching transistor electrically connected to the driving transistor; and
an anode initialization transistor, which receives a first initialization voltage, initializes a voltage of an anode of the light-emitting element, and is an n-type transistor, and
wherein a first length of a channel of the driving transistor is greater than a second length of a channel of the anode initialization transistor, and the second length of the channel of the anode initialization transistor is greater than a third length of a channel of each of the at least one switching transistor.

18. The electronic device of claim 17, wherein the substrate comprises:
a first area in which the driving transistor and the at least one switching transistor are disposed; and
a second area in which the anode initialization transistor is disposed.

19. The electronic device of claim 18,
wherein the pixel driving circuit further comprises a first body pattern to which a first power voltage having a relatively high level of voltage is applied and a second body pattern to which a low gate voltage having a relatively low level of voltage is applied,
wherein the first body pattern extends in a first direction and defines a boundary between the first area and the second area, and
wherein the second body pattern is disposed in the second area on the substrate, has a width in the first direction, and extends in a second direction intersecting the first direction.

20. The electronic device of claim 19,
wherein each of the driving transistor and the at least one switching transistor is a p-type transistor,
wherein each of the driving transistor, the anode initialization transistor, and the at least one switching transistor comprises a body electrode,
wherein the first power voltage having the relatively high voltage level is applied to the body electrode of the driving transistor and the body electrode of the at least one switching transistor, and
wherein the low gate voltage having the relatively low voltage level is applied to the body electrode of the anode initialization transistor.
